(19) United States
(12) Patent Application Publication
(10) Pub. No.: US 2025/0107349 A1
(43) Pub. Date: Mar. 27, 2025

(54) DISPLAY DEVICE

(71) Applicant: LG Display Co., Ltd., Seoul (KR)

(72) Inventors: Sungbin SHIM, Yangsan-si (KR); Dahye KWON, Seoul (KR); JunHyeok YANG, Seoul (KR); SangWon LEE, Paju-si (KR)

(73) Assignee: LG Display Co., Ltd., Seoul (KR)

(21) Appl. No.: 18/891,919

(22) Filed: Sep. 20, 2024

(30) Foreign Application Priority Data
Sep. 21, 2023 (KR) 10-2023-0126388

(51) Int. Cl. H10K 59/122; H10K 59/124; H10K 59/80

(52) U.S. Cl. CPC H10K 59/122; H10K 59/124; H10K 59/8792

(57) ABSTRACT

A display device includes a substrate on which a plurality of sub pixels are defined, each sub pixel having an emitting area and a non-emitting area. The display device further includes a thin film transistor disposed in each of the plurality of sub pixels, a planarization layer disposed on the thin film transistor and including a first opening disposed in at least one of the emitting areas, a first electrode disposed on an upper surface of the planarization layer and the first opening in at least one of the plurality of sub pixels and connected to the thin film transistor, and a bank exposing a part of the first electrode on the planarization layer and defining the emitting area. The first electrode includes a first convex and concave pattern formed in an area at the first opening.

### CROSS-REFERENCE TO RELATED APPLICATIONS

This application claims priority to Korean Patent Application No. 10-2023-0126388 filed on Sep. 21, 2023, in the Korean Intellectual Property Office, the entire contents of which is hereby expressly incorporated by reference into the present application.

### BACKGROUND

### Field

The present disclosure relates to a display device, and particularly, to a display device securing improvement in light extraction efficiency.

### Discussion of the Related Art

Liquid crystal display (LCD) devices and organic light emitting display (OLED) devices have been widely used so far, and they are applied to a wider range of fields.

Unlike a liquid crystal display (LCD) device provided with a backlight, an organic light emitting display (OLED) device needs no additional light source.

Accordingly, the organic light emitting display (OLED) device can become thin and lightweight, ensure processing advantages, and be driven at low voltage thereby securing less power consumption. Above all, the organic light emitting display device comprises a self-light emitting diode, and each layer thereof can be formed of an organic thin film, ensuring more excellent flexibility and elasticity than other display devices.

### SUMMARY OF THE DISCLOSURE

One objective of the present disclosure is to provide a display device that reflects light proceeding toward the lateral surface of the display device forward to secure improvement in front luminance.

Another objective of the present disclosure is to provide a display device that minimizes a white angle difference depending on viewing angles.

Another objective of the present disclosure is to provide a display device that is driven at low power, based on the improvement in light extraction efficiency.

Yet another objective of the present disclosure is to provide a display device that minimizes the leakage of light or a mixture of colors.

Objects of the present disclosure are not limited to the above-mentioned objects, and other objects, which are not mentioned above, can be clearly understood by those skilled in the art from the following descriptions.

A display device according to one embodiment of the present disclosure comprises a substrate on which a plurality of sub pixels are defined where each sub pixel comprises an emitting area and a non-emitting area, a thin film transistor disposed in each of the plurality of sub pixels, a planarization layer disposed on the thin film transistor, and comprising a first opening disposed in at least one of the emitting areas, a first electrode disposed on an upper surface of the planarization layer and the first opening in at least one of the plurality of sub pixels, and connected to the thin film transistor, and a bank exposing a part of the first electrode on the planarization layer and defining the emitting area, wherein the first electrode comprises a first convex and concave pattern formed in an area at the first opening, thereby enhancing light extraction efficiency and enabling driving at low power.

Other detailed matters of the example embodiments are included in the detailed description and the drawings.

In the embodiments of the present disclosure, the convex and concave pattern comprised of, for example, a material of high reflectivity is disposed on the lateral surface of the planarization layer, corresponding to the emitting area, to reflect light proceeding toward the lateral surface of the planarization layer forward, thereby enhancing front luminance.

In the embodiment of the present disclosure, the convex and concave pattern comprised of, for example, a material of high reflectivity is additionally disposed on the planarization layer, corresponding to the non-emitting area, thereby minimizing the leakage of light and a mixture of colors.

In the embodiment of the present disclosure, improvement in light extraction efficiency leads to improvement in the lifespan of a light emitting diode and low-power driving.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an embodiment of the present disclosure;

FIG. 2A is a cross-sectional view along line II-II′ of FIG. 1;

FIG. 2B is an enlarged view of area A in FIG. 2A;

FIGS. 3A-3C are schematic enlarged plan views of sub pixels with different shapes of a first opening of the display device according to the embodiment of the present disclosure;

FIG. 4 is a table showing results of comparison of a light emission efficiency of the display device to which one embodiment of the present disclosure is applied and the light emission efficiency of the display device to which the embodiment is not applied;

FIG. 5 is a cross-sectional view of a display device according to another embodiment of the present disclosure;

FIG. 6 is a cross-sectional view of a display device according to yet another embodiment of the present disclosure; and

FIGS. 7A to 7G are flowcharts for describing a manufacturing method of a display device according to an embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, yet another element or layer can be interposed directly on the another element or layer, or be interposed directly therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiments of the present disclosure are operatively coupled and configured.

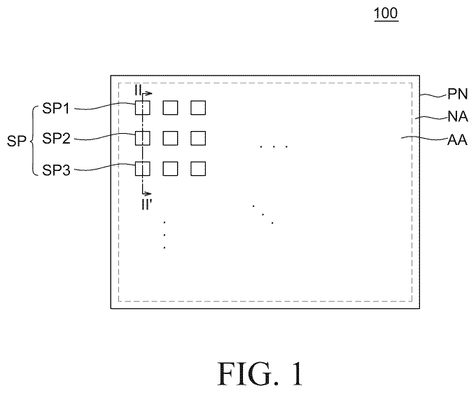

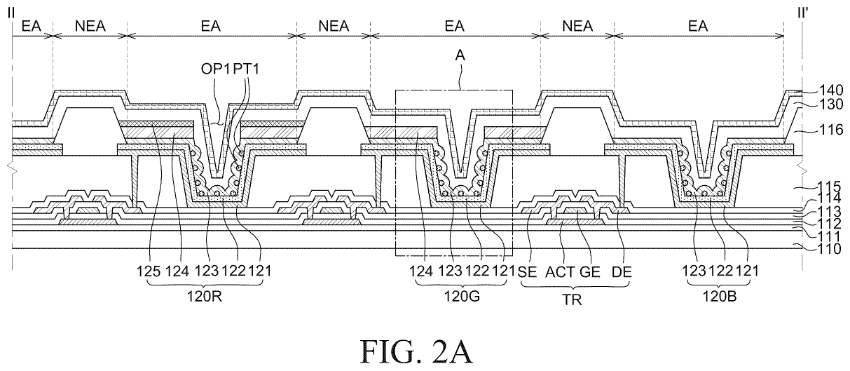

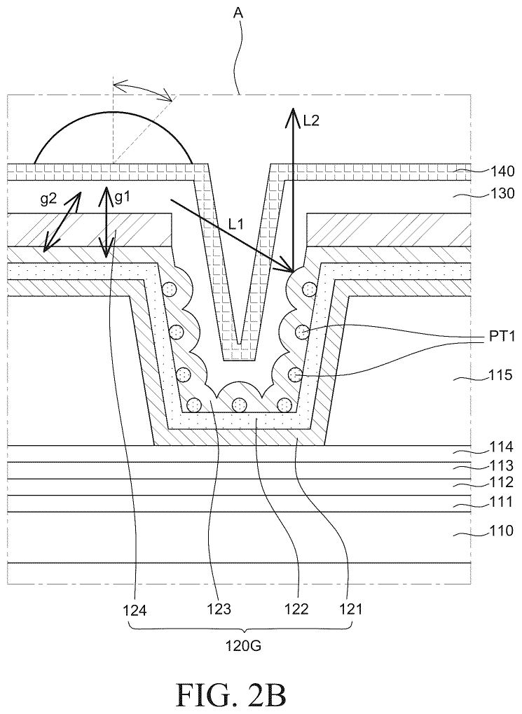

FIG. 1 is a schematic diagram of a display device according to an embodiment of the present disclosure. FIG. 2A is a cross-sectional view along line II-II′ of FIG. 1. FIG. 2B is an enlarged view of area A in FIG. 2A. For convenience of description, FIG. 1 shows a display panel (PN), among a variety of components of a display device 100.

Referring to FIG. 1, the display device 100 can comprise a display panel PN comprising a plurality of sub pixels SP.

The display panel PN as a component for displaying an image to the user can comprise a plurality of sub pixels SP. In the display panel PN, a plurality of scan lines and a plurality of data lines cross each other, and each of the plurality of sub pixels can connect to the scan line and the data line. In addition, each of the plurality of sub pixels SP can connect to a high potential power line, a low potential power line, a reference line and the like.

In the display panel PN, an active area AA, and a non-active area NA surrounding the active area AA can be defined. The non-active area NA can surround the active area AA entirely or only in parts.

The active area AA denotes an area where an image is displayed, in the display device 100. In the active area AA, the plurality of sub pixels SP constituting a plurality of pixels, and a circuit for driving the plurality of sub pixels SP can be disposed. The sub pixel SP is a minimum unit constituting the active area AA, and n numbers of sub pixels SP can constitute one pixel. Specifically, each sub pixel SP, which is a component for displaying one color, can be defined as an area where the plurality of scan lines disposed in a first direction and the plurality of data lines disposed in a second direction different from the first direction cross. Herein, the first direction can be a horizontal direction in FIG. 1, and the second direction can be a vertical direction in FIG. 1, but not limited thereto. Each sub pixel SP can comprise an emitting area EA where light emits, and a non-emitting area NEA where light does not emit. Each of the plurality of sub pixels SP can be divided into a first sub pixel SP1, a second sub pixel SP2 and a third sub pixel SP3. The first sub pixel SP1 can be a red pixel, the second sub pixel SP2 can be a green pixel, and the third sub pixel SP3 can be a blue pixel, but not limited thereto. Each sub pixel SP can have an individual emitting area EA.

In each of the plurality of sub pixels SP [symbol] a light emitting diode and a driving transistor for driving the light emitting diode and the like can be disposed. The light emitting diode can be defined in a different manner, depending on the sort of display panel. For example, in the case where the display panel is an organic light emitting display panel, the light emitting diode can be an organic light emitting diode (OLED).

In the active area (AA), a plurality of lines delivering various types of signals to the plurality of sub pixels SP can be disposed. The plurality of lines, for example, can comprise a plurality of data lines providing a data voltage to each of the plurality of sub pixels SP, a plurality of scan lines providing a scan signal to each of the plurality of sub pixels SP, and the like. The plurality of scan lines can extend in the active area AA in one direction and connect to the plurality of sub pixels SP, while the plurality of data lines can extend in the active area AA in a direction different from the one direction and connect to the plurality of sub pixels SP. In addition, in the active area AA, a low potential power line, a high potential power line and the like can be further disposed, but not limited thereto.

The non-active area NA that is an area where an image is not displayed can be defined as an area extending from the active area AA. In the non-active area NA, link lines for delivering a signal to the sub pixels SP of the active area AA and a pad electrode or a driving IC such as a gate driver IC and a data driver IC, and the like can be disposed.

However, the non-active area NA can be placed on the rear surface of the display panel PN, i.e., on a surface without sub pixels SP, or can be omitted, but not limited to the one illustrated in the drawings.

Referring to FIGS. 1 and 2A, the display panel PN comprises a substrate 110, a buffer layer 111, a gate insulation layer 112, an interlayer insulation layer 113, a passivation layer 114, a planarization layer 115, a thin film transistor TR, a first electrode 120R, 120G, 120B, a light emitting part 130, and a second electrode 140. The display panel PN of the present disclosure can be constituted based on a top emission method. For example, the display panel PN is based on the method by which light emitting from the light emitting part 130 emits toward the upper portion of the second electrode 140. In the top emission method, the second electrode 140 can be comprised of an electrode of transmittance or an electrode of semi-transmittance to allow light emitting from the light emitting part 130 to proceed upward. Additionally, the second electrode 140 can be formed to be very thin to enhance transparency. Detailed description in relation to this is provided hereinafter.

The substrate 110 as a support member for supporting another component of the display device 100 can be comprised of an insulation material. The substrate 110, for example, can be comprised of glass or resin and the like. Additionally, the substrate 110 can comprise plastics such as polymer or polyimide (PI) and the like or can be comprised of a material having flexibility.

The buffer layer 111 can be disposed on the substrate 110. The buffer layer 111 can reduce the infiltration of moisture or impurities through the substrate 110. The buffer layer 111, for example, can be comprised of a single layer of silicon oxide (SiOx) or silicon nitride (SiNx) or multiple layers of silicon oxide (SiOx) or silicon nitride (SiNx), but not limited thereto. However, the buffer layer 111 can be omitted depending on the sort of substrate 110 or the sort of driving transistor, and not limited thereto.

The thin film transistor TR comprising an active layer ACT, a gate electrode GE, a source electrode SE and a drain electrode DE can be disposed on the buffer layer 111.

First, the active layer ACT of the thin film transistor TR can be disposed on the buffer layer 111. The active layer ACT can be comprised of a semiconductor material such as an oxide semiconductor, amorphous silicon or polysilicon and the like, but not limited thereto. Additionally, another transistor such as a switching transistor, a sensing transistor, an emission control transistor and the like can be disposed in addition to the thin film transistor TR, and the active layers of such transistors can also be comprised of a semiconductor material such as an oxide semiconductor, amorphous silicon or polysilicon and the like, but not limited thereto. Further, the active layer of a transistor such as a thin film transistor TR, a switching transistor, a sensing transistor, an emission control transistor and the like included in a pixel circuit can be comprised of the same material or a different material.

The gate insulation layer 112 can be disposed on the active layer ACT. The gate insulation layer 112 as an insulation layer insulating the active layer ACT from the gate electrode GE electrically can be comprised of a single layer of silicon oxide (SiOx) or silicon nitride (SiNx) or multiple layers of silicon oxide (SiOx) or silicon nitride (SiNx), but not limited thereto.

The gate electrode GE can be disposed on the gate insulation layer 112. The gate electrode GE can be comprised of an electrically conductive material, e.g., copper (Cu), aluminum (Al), molybdenum (Mo), nickel (Ni), titanium (Ti), chrome (Cr), or an alloy thereof, but not limited thereto.

The interlayer insulation layer 113 can be disposed on the gate electrode GE. The interlayer insulation layer 113 can have a contact hole for connecting each of the source electrode SE and the drain electrode DE to the active layer ACT. The interlayer insulation layer 113 as an insulation layer for protecting components thereunder can be comprised of a single layer of silicon oxide (SiOx) or silicon nitride (SiNx) or multiple layers of silicon oxide (SiOx) or silicon nitride (SiNx), but not limited thereto.

The source electrode SE and the drain electrode DE connecting with the active layer ACT electrically can be disposed on the interlayer insulation layer 113. The source electrode SE and the drain electrode DE can be comprised of an electrically conductive material, e.g., copper (Cu), aluminum (Al), molybdenum (Mo), nickel (Ni), titanium (Ti), chrome (Cr), or an alloy thereof, but not limited thereto.

The passivation layer 114 can be disposed on the source electrode SE and the drain electrode DE. The passivation layer 114 is an insulation layer for protecting components thereunder. For example, the passivation layer 114 can be formed of an inorganic insulation material such as silicon oxide (SiOx) or silicon nitride (SiNx) and the like, and can also be formed of an organic insulation material and the like, but not limited thereto.

The planarization layer 115 can be disposed on the passivation layer 114. The planarization layer 115 can planarize the upper portion of the pixel circuit comprising the thin film transistor TR. The planarization layer 115 can be comprised of a single layer or multiple players, and for example, can be comprised of a benzocyclobutene-based organic material or an acryl-based organic material, but not limited thereto. As described hereinafter, the light emitting part 130 comprised of a plurality of organic layers is disposed on the planarization layer 115, and at this time, the planarization layer can have a height of 0.8-1.5 μm so that light emission efficiency may not deteriorate due to uneven deposition of the light emitting part 130, which is caused by steps of a first opening OP1 and the planarization layer 115. Specifically, the planarization layer 115 can have a height of 1.0-1.2 μm.

The planarization layer 115 can comprise a first opening OP1 that is disposed in at least one of the emitting areas EA.

At least one first opening OP1 can be formed on the planarization layer 115. In FIGS. 2A and 2B, the planarization layer 115 is completely removed at the first opening OP1, and the passivation layer 114 is exposed, but not limited thereto, and additionally, a part of the planarization layer 115 can only be removed. For example, while the passivation layer 114 is not exposed, the first opening OP1 can be shaped into a groove that is recessed downward.

Additionally, since the first opening OP1 exposes the lateral surface of the planarization layer 115, the first electrode 120R, 120G, 120B can be disposed on the upper surface of the passivation layer 114 and the lateral surface of the planarization layer 115, in the emitting area EA. As described hereinafter, since the first electrode 120R, 120G, 120B disposed at the first opening OP1 comprises a first convex and concave pattern PT1, the first electrode 120R, 120G, 120B can reflect light emitting to the lateral surface or the lower portion thereof from the light emitting part 130 and change a path of the light.

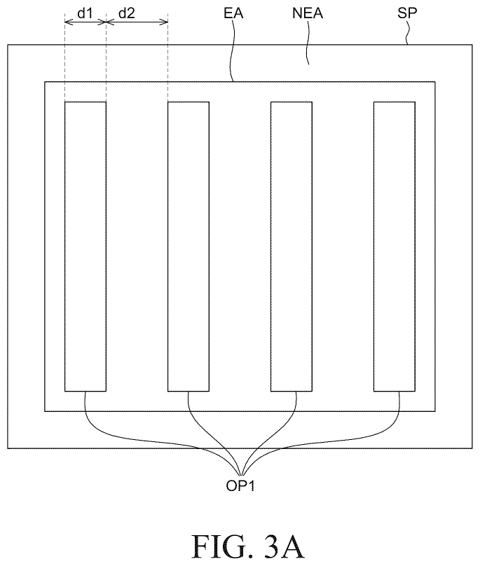

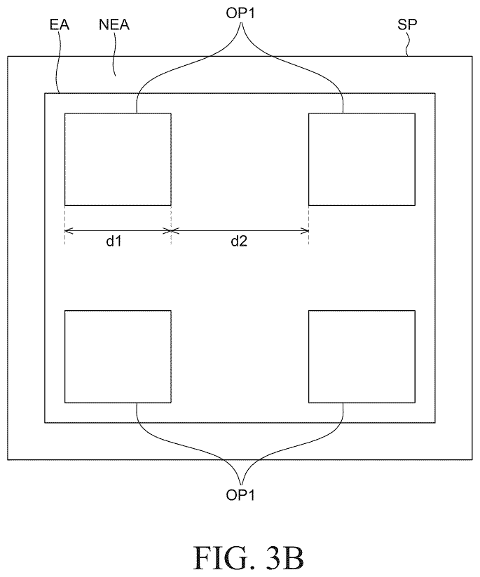

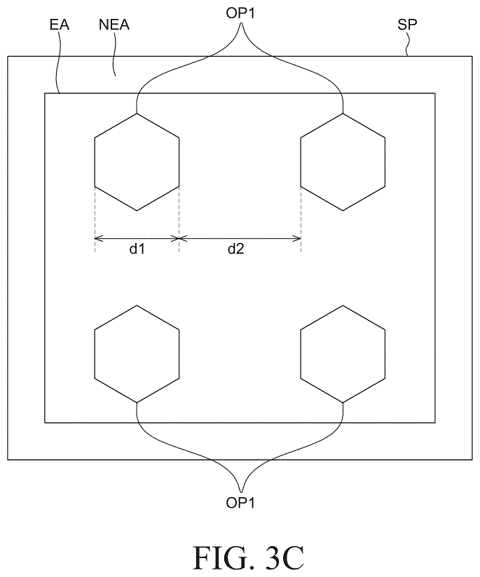

FIGS. 3A-3C are schematic enlarged plan views of sub pixels with different shapes of the a first opening of the display device of according to the embodiment of the present disclosure.

Referring to FIGS. 3A-3C together, the first opening OP1 can be shaped into a planar slit, rectangle (such as square) or hexagon. Additionally, a plurality of first opening OP1 is formed in the emitting area EA of one sub pixel SP to enhance light extraction efficiency. In the case where the first opening OP1 is shaped into a rectangle or a hexagon as illustrated in FIGS. 3B and 3C, the first opening OP1 can be disposed in a 2×2 matrix form, in one sub pixel SP, but not limited thereto.

Additionally, the first opening OP1 can be formed considering the width d1 and the gap d2 of the first opening as well as the height of the planarization layer 115, so that light can be reflected forward by the first convex and concave pattern PT1 disposed on the lateral surface of the planarization layer 115, at the first opening OP1. Specifically, the width d1 of the first opening can be 2 μm-6 μm or 3 μm-5 μm, and at this time, the gap d2 between the first openings can be 4 μm-6 μm. For example, the width d1 of the first opening and the gap d2 between the first openings can be at a ratio of 1:1-1:1.5. In the case where a plurality of first openings OP1 is provided, the height of the planarization layer 115 is 0.8 μm-1.5 μm or 1.0 μm-1.2 μm, and the ratio of the width d1 of the first opening OP1 to the gap d2 between the first openings OP1 satisfies the above ratio, the light emitting part 130 comprised of a plurality of organic layers is evenly deposited on the planarization layer 115, to enhance light emission efficiency.

Referring to FIGS. 2A and 2B together, the first opening OP1 is formed at the planarization layer 115, in the emitting area EA, to expose the passivation layer 114 disposed under the planarization layer 115.

A plurality of light emitting diodes can be disposed at each of the plurality of sub pixels SP, on the planarization layer 115. The light emitting diode as a component emitting light by being applied a current can comprise a red light emitting diode emitting red light, a green light emitting diode emitting green light, and a blue light emitting diode emitting blue light, and based on a combination thereof, the light emitting diode can embody light of a variety of colors comprising white. For example, the light emitting diode can be an organic light emitting diode.

The light emitting diode can comprise a first electrode 120R, 120G, 120B, a light emitting part 130, and a second electrode 140.

The first electrode 120R, 120G, 120B can be disposed on the planarization layer 115. Specifically, the first electrode 120R, 120G, 120B can be disposed on the upper surface of the planarization layer 115 and at a first opening OP1 in each of the plurality of sub pixels SP. Accordingly, the first electrode 120R, 120G, 120B can contact the passivation layer 114. Additionally, the first electrode 120R, 120G, 120B can electrically connect to the drain electrode DE of the thin film transistor TR through a contact hole formed at the passivation layer 114 and the planarization layer 115.

The first electrode 120R, 120G, 120B, as a layer for providing holes to the light emitting part 130, can comprise a reflective layer 122 and at least one transparent conductive layer disposed on one surface of the reflective layer 122.

Specifically, the reflective layer 122 can be disposed on the upper surface of the planarization layer 115 and at the first opening OP1. The reflective layer 122 can be comprised of an opaque conductive material having high reflectivity, e.g., silver (Ag).

The transparent conductive layer can be comprised of a transparent and electrically conductive material of high work function, to provide holes to the light emitting part 130 and release light emitted from the light emitting part 130. The transparent and electrically conductive material, for example, can be comprised of indium tin oxide (ITO), but not limited thereto.

Referring to FIG. 2A, the transparent conductive layer can comprise a first transparent conductive layer 121 under the reflective layer 122 and a second transparent conductive layer 123 on the reflective layer 122, and each sub pixel SP can further comprise a third transparent conductive layer 124 and/or a fourth transparent conductive layer 125. At this time, the first transparent conductive layer 121 and the second transparent conductive layer 123 can inject holes into a light emitting layer of the light emitting part 130 and protect the reflective layer 122. Additionally, the third transparent conductive layer 124 and the fourth transparent conductive layer 125 can increase a distance from the second electrode 140 to the reflective layer 122 so that the luminance of light emitted from the light emitting layer of each light emitting part 130 and reflected between the third and the fourth transparent conductive layer 124 and 125 and the second electrode 140, can be amplified by constructive interference. Accordingly, as described hereinafter, the third transparent conductive layer 124 and the fourth transparent conductive layer 125 are selectively disposed in the sub pixel SP, to embody a micro cavity structure.

For example, the first electrode 120R of the first sub pixel SP1 can comprise a first transparent conductive layer 121, a reflective layer 122 on the first transparent conductive layer 121, a second transparent conductive layer 123 on the reflective layer 122, a third transparent conductive layer 124 on the second transparent conductive layer 123, and a fourth transparent conductive layer 125 on the third transparent conductive layer 124. At this time, the third transparent conductive layer 124 and the fourth transparent conductive layer 125 can be disposed only on the planarization layer 115, without being disposed at the first opening OP1.

The first electrode 120G of the second sub pixel SP2 can comprise a first transparent conductive layer 121, a reflective layer 122 on the first transparent conductive layer 121, a second transparent conductive layer 123 on the reflective layer 122, and a third transparent conductive layer 124 on the second transparent conductive layer 123. At this time, the third transparent conductive layer 124 can only be disposed on the planarization layer 115, without being disposed at the first opening OP1.

The first electrode 120B of the third sub pixel SP3 can comprise a first transparent conductive layer 121, a reflective layer 122 on the first transparent conductive layer 121, and a second transparent conductive layer 123 on the reflective layer 122.

For example, the first electrode 120R, 120G, 120B can have a different thickness in each of the first sub pixel SP1, the second sub pixel SP2 and the third sub pixel SP3. For example, in the case where the first sub pixel SP1 is a red sub pixel, the second sub pixel SP2 is a green sub pixel, and the third sub pixel SP3 is a blue sub pixel, the first electrode 120R of the first sub pixel SP1 can be thicker than the first electrode 120G of the second sub pixel SP2, and the first electrode 120G of the second sub pixel SP2 can be thicker than the first electrode 120B of the third sub pixel SP3. For example, the first electrode 120R, 120G, 120B can each have a micro cavity structure in which light having a wavelength corresponding to light emitted from a corresponding sub pixel SP in the first sub pixel SP1, the second sub pixel SP2 and the third sub pixel SP3 can be amplified. For example, light emitted from the light emitting part 130 can be reflected repeatedly between the first electrode 120R, 120G, 120B and the second electrode 140. At this time, each of the first electrode 120R, 120G, 120B can be disposed to have a different thickness in each sub pixel SP, so that the energy of reflected light with corresponding wavelength can be multiplied, thereby increasing the luminance of light reflected by constructive interference. Accordingly, the first electrode 120R of the first sub pixel SP1 emitting red light can be the thickest one, and the first electrode 120B of the third sub pixel SP3 emitting blue light can be the thinnest one.

Additionally, the first electrode 120R, 120G, 120B can comprise a first convex and concave pattern PT1 disposed in the area where the first opening OP1 is formed. The first convex and concave pattern PT1 can reflect light, proceeding toward the lateral surface or lower portion thereof, forward and change the path of the light. Specifically, the first convex and concave pattern PT1 can be shaped into a particle formed by coagulating from the reflective layer 122. Accordingly, the first convex and concave pattern PT1 can protrude further toward the inside of the first opening OP1 than the reflective layer 122. Additionally, the second transparent conductive layer 123 covering the first convex and concave pattern PT1 on the reflective layer 122 can have a curved shape because of the shape of the first convex and concave pattern PT1.

Specifically, referring to FIG. 2B together, a gap g1, g2 of the micro cavity is determined with respect to the front surface thereof, and can vary depending on viewing angles, and accordingly, the side luminance decreases unlike the front luminance, so that the luminance uniformity depending on viewing angles can deteriorate. Thus, lateral light L1, emitting from the light emitting part 130 disposed on the planarization layer 115 and proceeding toward the lateral surface, can be reflected by the first convex and concave pattern PT1, and its path can change to a path of front light L2. At this time, the first convex and concave pattern PT1 can be comprised of a material of high reflectivity, to enhance reflection efficiency. The first convex and concave pattern PT1, for example, can be formed from the reflective layer 122 comprising silver (Ag). Specifically, the first convex and concave pattern PT1 can be formed in such a way that silver (Ag) of the reflective layer 122 is exposed to ultraviolet rays and is thermally treated. In the case where silver (Ag) is exposed to ultraviolet rays, the first convex and concave pattern PT can be formed based on thermal treatment of the reflective layer 122 since silver (Ag) particles are precipitated.

Specifically, the first convex and concave pattern PT1 can be formed in such a way that the reflective layer 122 comprising silver (Ag) is exposed to ultraviolet rays and thermally treated. In the case where silver (Ag) is exposed to ultraviolet rays, silver (Ag) particles can be precipitated, and with the particles, the first convex and concave pattern PT1 can be formed.

A bank 116 can be disposed on the planarization layer 115 and the first electrode 120R, 120G, 120B. The bank 116 can cover the edge of the first electrode 120R, 120G, 120B and expose a portion of the upper surface of the first electrode 120R, 120G, 120B, to define the emitting area EA. Specifically, the bank 116 can cover the edges of the first transparent conductive layer 121 and the reflective layer 122 of the first electrode 120R, 120G, 120B. Accordingly, the bank 116 can expose a part of the first electrode 120R, 120G, 120B. For example, the bank 116 can divide the emitting area EA of the plurality of sub pixels SP. The bank 116 can be comprised of an insulation material to insulate the first electrodes 120R, 120G, 120B of adjacent sub pixels SP from each other. Additionally, the bank 116 can be comprised of a black material of a high light absorption rate to prevent a mixture of colors of adjacent sub pixels SP. The bank 116, for example, can be comprised of polyimide resin, acryl resin, or benzocyclobutene (BCB) resin, but not limited thereto.

The light emitting part 130 can be disposed on the first electrode 120R, 120G, 120B and the bank 160. The light emitting part 130 comprises a light emitting layer that emits light, based on a coupling of an electron and a hole. In the case where the display device 100 of one embodiment is an organic light emitting display device, the light emitting layer can be an organic light emitting layer comprising an organic material that emits light on its own, but not limited thereto. Additionally, the light emitting part 130, as a layer that emits light based on a coupling of an electron and a hole, can further comprise a hole injection layer, a hole transport layer, an electron transport layer, an electron injection layer and the like, to enhance light emission efficiency. The light emitting part 130, for example, can comprise a hole injection layer, a hole transport layer and a light emitting layer on the first electrode 120R, 120G, 120B, and comprise an electron transport layer and an electron injection layer between the light emitting layer and the second electrode 140. Additionally, to further enhance efficiency of a recoupling of a hole and an electron at the light emitting layer, the light emitting part 130 can further comprise a hole blocking layer or an electron blocking layer, but not be limited thereto.

The second electrode 140 can be disposed on the light emitting part 130. The second electrode 140 is a layer for providing electrons to the light emitting part 130. The second electrode 140, for example, can be comprised of an electrically conductive material of transmittance or semi-transmittance. The second electrode 140, for example, can be comprised of a transparent and electrically conductive material such as indium tin oxide (ITO), indium zinc oxide (IZO) and the like, but not limited thereto.

In the display device, an electrode having a different thickness can be disposed in each of the plurality of sub pixels emitting light of a different color, to enhance color purity. For example, each of the plurality of sub pixels can have a micro cavity structure corresponding to light emitting from a corresponding pixel. Additionally, since the gap of the micro cavity structure is determined with respect to the front surface thereof, the gap of a micro cavity can change depending on a change in the viewing angles. For example, light proceeding toward the lateral surface of the display device rather than the front surface of the display device experiences white angle difference (WAD) depending on an angle, and its color purity and luminance uniformity can deteriorate depending on viewing angles.

Accordingly, in the display device 100 of one embodiment, the first opening OP1 is formed at the planarization layer 115 in the emitting area EA, and the first electrode 120R, 120G, 120B comprising the first convex and concave pattern PT1 on the lateral surface of the planarization layer 115 is disposed at the first opening OP1, so that light emitting to the lateral surface of the planarization layer from the light emitting part 130 is reflected forward, thereby enhancing front luminance, and minimizing white angle difference depending on viewing angles.

Further, in the display device 100 of one embodiment, silver (Ag) particles of high reflectivity are used to form the first convex and concave pattern PT1, making it easier to enhance light extraction efficiency and making it possible to extend the lifespan of a light emitting diode.

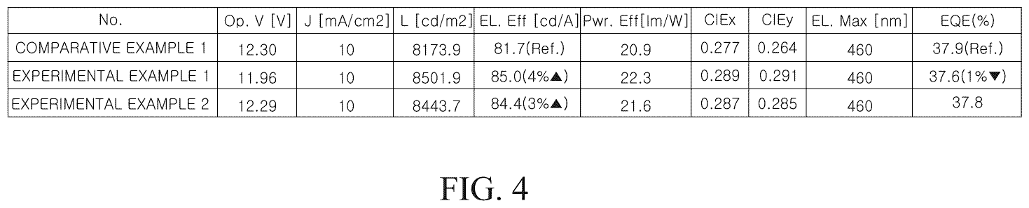

FIG. 4 is a table showing results of comparison of the light emission efficiency of the display device to which one embodiment of the present disclosure is applied and the light emission efficiency of the display device to which the embodiment of the present disclosure is not applied.

### Comparative Example 1

In a display device of comparative example 1, the planarization layer 115 has no first opening OP1, and the first electrode 120R, 120G, 120B comprises no first convex and concave pattern PT1.

### Experimental Example 1

In a display device of experimental example 1, the planarization layer 115 has a first opening OP1, and the width d1 and gap d2 of the first opening are both 4 μm.

### Experimental Example 2

In a display device of experimental example 2, as shown in the display device of experimental example 1, the planarization layer 115 has a first opening OP1, and the gap d2 between the first openings is 6 μm while the width d1 of the first opening is 4 μm.

At this time, in comparative example 1 and experimental examples 1 and 2, the height of the planarization layer 115 can be 1.0 μm-1.2 μm.

As a result of comparison of luminance L of comparative example 1 and experimental examples 1 and 2, the luminance of comparative example 1 and experimental examples 1 and 2 is 8173.9 cd/m², 8501.9 cd/m², and 8443.7 cd/m² respectively, and the luminance of experimental examples 1 and 2 improves further than the luminance of comparative example 1.

As a result of comparison of current efficiency EL. Eff of comparative example 1 and experimental examples 1 and 2, the current efficiency of comparative example 1 and experimental examples 1 and 2 is 81.7 cd/A, 85.0 cd/A respectively, and 84.4 cd/A, and the current efficiency of experimental example 1 improves further by about 4% than the current efficiency of comparative example 1, while the current efficiency of experimental example 2 improves further by about 3% than the current efficiency of comparative example 1.

Further, as a result of comparison of power efficiency Pwr. Eff of comparative example 1 and experimental examples 1 and 2, the power efficiency of each of comparative example 1 and experimental examples 1 and 2 is 20.9 Im/W, 22.3 Im/W, 21.6 Im/W, and the power efficiency of experimental examples 1 and 2 improves further than the power efficiency of comparative example 1.

For example, the planarization layer 115 can have at least one first opening OP1 in the emitting area EA, and the first convex and concave pattern PT1 formed by precipitating silver (Ag) of the reflective layer 122 can be disposed at the first opening OP1 to reflect light proceeding toward the lateral surface of the planarization layer, and can change the path of the light so that the light can proceed forward. For example, according to the present disclosure, light extraction efficiency and luminance can improve.

In particular, as shown in the table of FIG. 4, in the case where the width d1 and gap d2 of the first opening is at a ratio of 1:1-1:1.5, while the height of the planarization layer 115 is 1.0 μm-1.2 μm, the light emitting part 130 can be evenly deposited on the planarization layer 115, and light proceeding toward the lateral surface or lower portion of the planarization layer can be reflected forward by the first convex and concave pattern PT1 disposed at the first opening OP1, thereby maximizing light extraction efficiency.

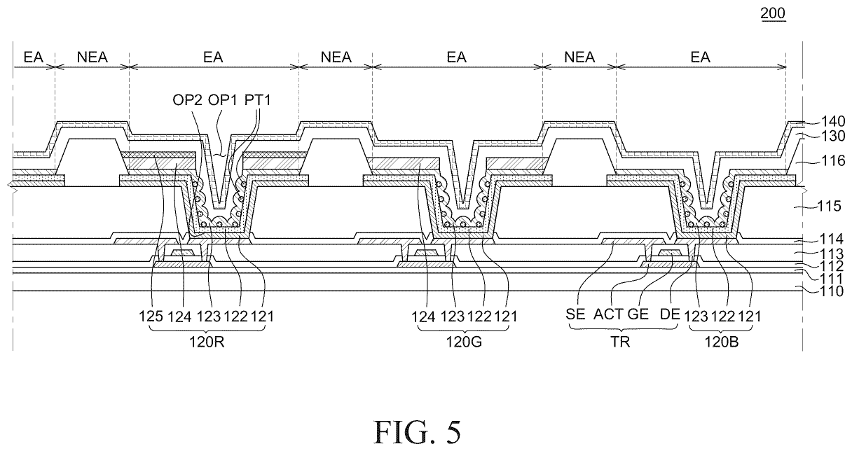

FIG. 5 is a cross-sectional view of a display device according to another embodiment of the present disclosure. The display device 200 of FIG. 5 and the display device 100 of FIGS. 1-3C are substantially identical except for the presence or absence of a second opening OP2 and the positions of disposition of the first electrode 120R, 120G, 120B and the thin film transistor TR. Accordingly, their common features are not described or may be briefly described.

Referring to FIG. 5, the passivation layer 114 can comprise at least one second opening OP2. The second opening OP2 can be disposed to overlap the first opening OP1, and specifically, can be disposed under the first opening OP1.

At this time, the first electrode 120R, 120G, 120B can be disposed to extend to the second opening OP2 as well as the first opening OP1. The first electrode 120R, 120G, 120B can connect to the thin film transistor TR through the second opening OP2, without an additional contact hole.

Thus, the thin film transistor TR can be disposed in the emitting area EA.

At this time, a total of heights of the passivation layer 114 and the planarization layer 115 can be 0.8 μm-1.5 μm, so that light emission efficiency may not deteriorate due to uneven deposition of the light emitting part 130, caused by the step of the first opening OP1 and the second opening OP2 and the planarization layer 115. Specifically, a total of the heights of the passivation layer 114 and the planarization layer 115 can be 1.0 μm-1.2 μm.

In the case of a display device 200 of another embodiment, in the emitting area EA, the first opening OP1 is formed at the planarization layer 115, while the second opening OP2 is formed at the passivation layer 114, and the first electrode 120R, 120G, 120B, comprising the first convex and concave pattern PT1 formed by precipitating silver (Ag) particles of high reflectivity, is disposed on the lateral surface of the planarization layer 115, at the first opening OP1 and the second opening OP2, and reflects light, emitting to the lateral surface of the planarization layer from the light emitting part 130, forward to enhance front luminance.

Additionally, in the display device 200 of another embodiment, the first electrode 120R, 120G, 120B can connect to the thin film transistor TR through the second opening OP2, without an additional contact hole.

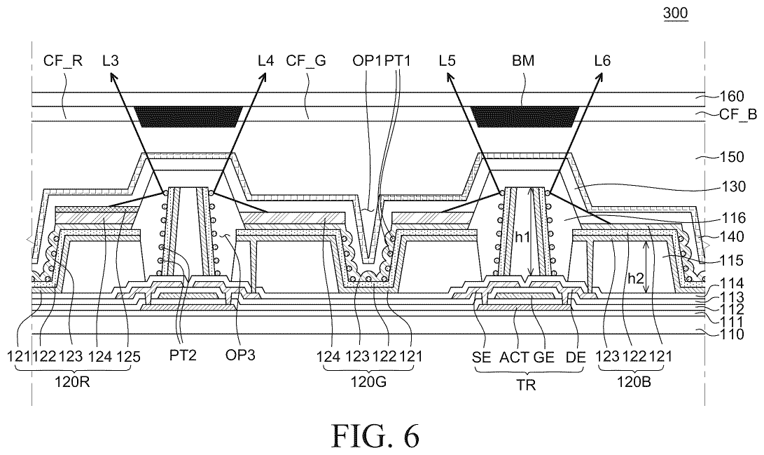

FIG. 6 is a cross-sectional view of a display device according to yet another embodiment of the present disclosure. The display device 300 of FIG. 6 and the display device 100 of FIGS. 1-3C are substantially identical, except for the height of the planarization layer 115 and the presence or absence of a second convex and concave pattern PT2, a color filter, a black matrix BM and an upper substrate 160 disposed in the non-emitting area NEA. Accordingly, their common features are not described or may be briefly described.

Referring to FIG. 6, the planarization layer 115 can comprise a third opening OP3 disposed in at least one of the non-emitting areas NEA. Since the third opening OP3 is disposed in the non-emitting area NEA, the third opening OP3 can be disposed to overlap the black matrix BM. At this time, a part of the planarization layer 115, disposed in the non-emitting area NEA, has a greater height h1 than the height h2 of a part of the planarization layer 115, disposed in the emitting area EA.

At this time, the first electrode 120R, 120G, 120B can extend to and be disposed at the third opening OP3. Additionally, the first electrode 120R, 120G, 120B disposed in the non-emitting area NEA can comprise a first transparent conductive layer 121 and a reflective layer 122 on the first transparent conductive layer 121 only, but not be limited thereto. Accordingly, the first electrode 120R, 120G, 120B disposed in the emitting area EA and the first electrode 120R, 120G, 120B disposed in the non-emitting area NEA can be spaced from each other due to the third opening OP3. Further, the first electrode 120R, 120G, 120B can further comprise a second convex and concave pattern PT2.

Like the first convex and concave pattern PT1, the second convex and concave pattern PT2 can be formed in such a way that silver (Ag) particles are precipitated by exposing the reflective layer 122 comprising silver (Ag) to ultraviolet rays and thermally treating the same. At this time, the second convex and concave pattern PT2 can be disposed on the lateral surface of the planarization layer 115 at the third opening OP3. Accordingly, at least a part of the second convex and concave pattern PT2 can be disposed at a position higher than the position of the planarization layer 115 disposed in the emitting area EA. For example, a part of the second convex and concave pattern PT2 disposed in the non-emitting area NEA can be disposed closer to the color filter and the black matrix BM than the first convex and concave pattern PT1 disposed in the emitting area EA. At this time, in the case where a plurality of light rays L3, L4, L5, L6 emitting from the light emitting part 130 of the emitting area EA passes through the color filter of an adjacent sub pixel SP toward the lateral surface of the planarization layer, a spot can occur to the display device 300 due to a mixture of colors. Thus, the plurality of light rays L3, L4, L5, L6 emitting from the light emitting part 130 of the emitting area EA can be reflected by the second convex and concave pattern PT2 disposed higher than the light emitting part 130 of the emitting area EA, and its path can change toward a color filter corresponding to each sub pixel SP, to prevent a mixture of colors.

The encapsulation layer 150 can be disposed on the second electrode 140. The encapsulation layer 150 can cover the light emitting diode from external moisture, air, impacts and the like. The encapsulation layer 150 can be formed in such a way that a plurality of inorganic layers and a plurality of organic layers are stacked alternately. The inorganic layer, for example, can be comprised of an inorganic insulation material such as silicon nitride (SiNx), silicon oxide (SiOx), aluminum oxide (AlOx) and the like, and the organic layer, for example, can be formed of epoxy polymer or acryl-based polymer, but not limited thereto.

A plurality of color filters can be disposed on the encapsulation layer 150. Specifically, a first color filter CF_R, a second color filter CF_G and a third color filter CF_B can be disposed on the second electrode 140, in the emitting area EA. For example, the first color filter CF_R can be disposed to correspond to the emitting area EA of the first sub pixel SP1 and can be a red color filter. The second color filter CF_G can be disposed to correspond to the emitting area EA of the second sub pixel SP2 and can be a green color filter. The third color filter CF_B can be disposed to correspond to the emitting area EA of the third sub pixel SP3 and can be a blue color filter.

The black matrix BM can be disposed among the plurality of color filters. The black matrix BM can be disposed in the non-emitting area NEA, in each sub pixel SP. Accordingly, the black matrix BM can be disposed in an area corresponding to the bank 116. The black matrix BM as a black insulation layer can block light from the inside or outside of the display device 300. Accordingly, the black matrix BM can prevent the colors of light passing through the plurality of color filters from mixing. Further, the black matrix BM in a reverse taper shape is illustrated, but not limited thereto.

The upper substrate 160 can be disposed on the color filter and the black matrix BM. Together with the encapsulation layer 150, the upper substrate 160 can protect the light emitting diode from external moisture, air, impacts and the like. The upper substrate 160, for example, can be comprised of a transparent insulation material, but not limited thereto.

In the display device 300 of yet another embodiment, the first opening OP1 is formed at the planarization layer 115 in the emitting area EA, and the first electrode 120R, 120G, 120B, comprising the first convex and concave pattern PT1 formed by precipitating silver (Ag) particles of high reflectivity, is disposed on the lateral surface of the planarization layer 115, at the first opening OP1, and reflects light, emitting to the lateral surface of the planarization layer from the light emitting part 130, forward to enhance front luminance.

In particular, in the display device 300 of yet another embodiment, the planarization layer 115 of the non-emitting area NEA is formed higher than the planarization layer 115 of the emitting area EA, and the second convex and concave pattern PT2 formed by precipitating silver (Ag) particles is additionally disposed on the lateral surface of the planarization layer 115 in the non-emitting area NEA, so that light emitting from the light emitting part 130 of the emitting area EA toward the lateral surface of the planarization layer 115 can be reflected to pass through a color filter corresponding to each sub pixel SP, thereby preventing the leakage of light and a mixture of colors.

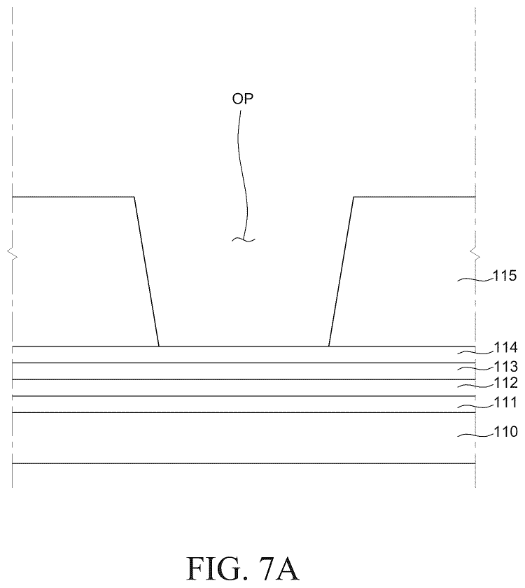

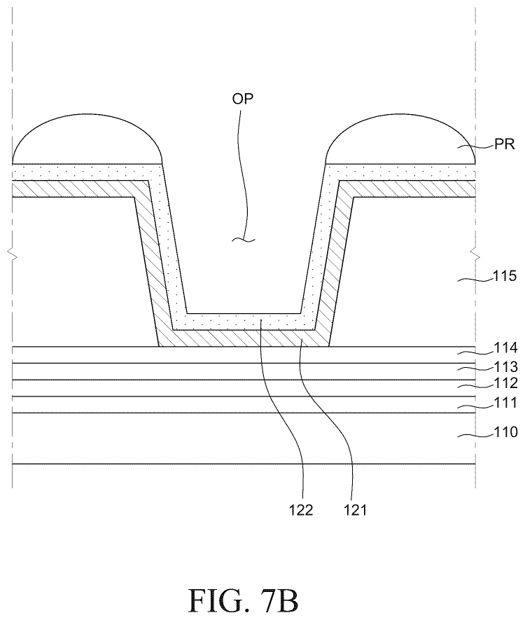

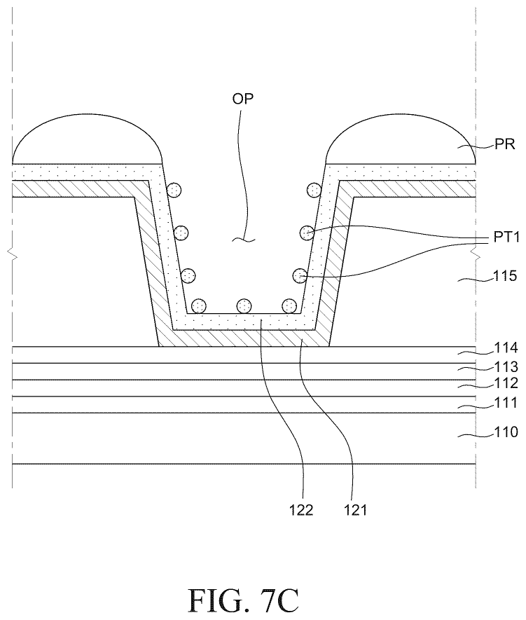

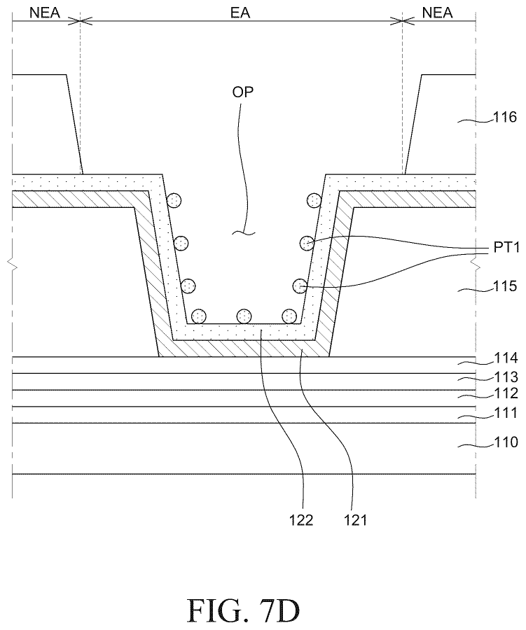

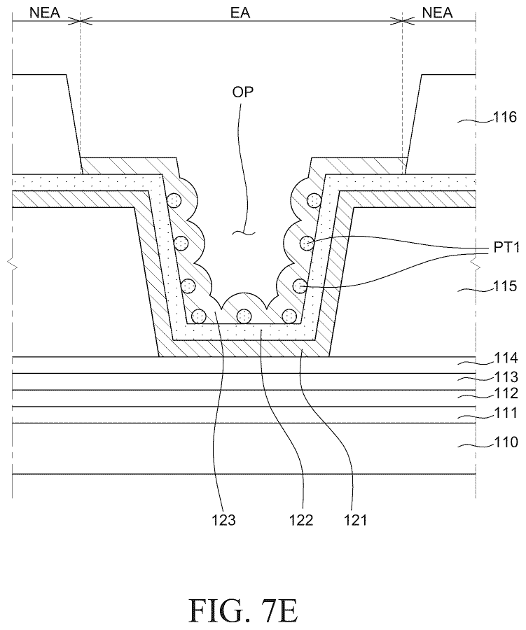

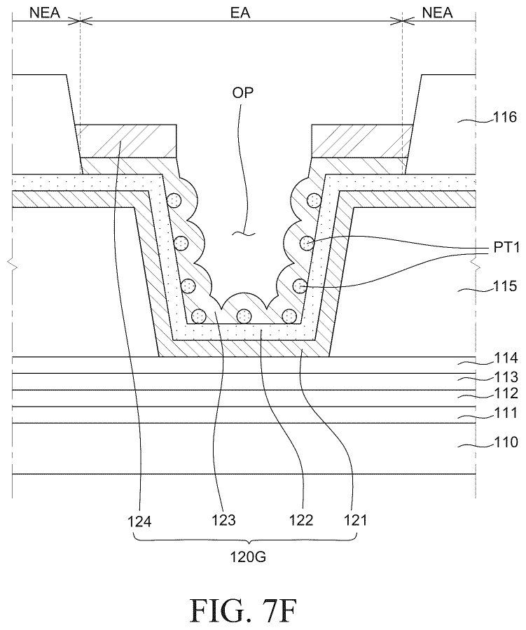

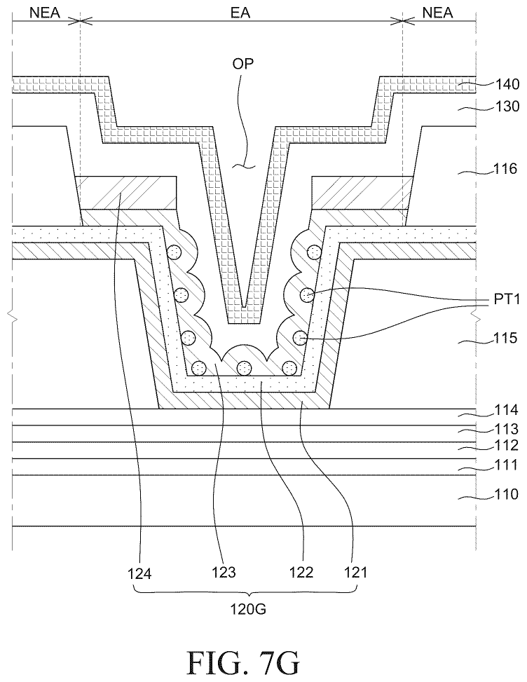

Hereinafter, a manufacturing method of a display device 100 according to one embodiment of the present disclosure is specifically described with reference to FIGS. 7A-7G.

FIGS. 7A-7G are flowcharts for describing a manufacturing method of a display device according to one embodiment of the present disclosure. For convenience of description, in FIGS. 7A-7G, a part of the second sub pixel SP2 is illustrated in an enlarged manner.

First, referring to FIG. 7A, etching a part of the

planarization layer 115 is performed to form at least one first opening OP1. Specifically, forming the first opening OP1 can be carried out consecutively by applying photoresist on the planarization layer 115, and selectively exposing the photoresist to light.

Then referring to FIG. 7B, the first transparent conductive layer 121 and the reflective layer 122 can be deposited consecutively on the planarization layer 115 and the first opening OP1. At this time, photoresist PR can be applied to prevent a part of the reflective layer 122, disposed on the upper surface of the planarization layer 115, from being exposed to ultraviolet rays.

Referring to FIG. 7C, forming the first convex and concave pattern PT1 can be performed. Specifically, a part of the reflective layer 122, to which photoresists PR is not applied, is exposed to ultraviolet rays and thermally treated, to precipitate silver (Ag), and accordingly, the first convex and concave pattern PT1 can be formed on the reflective layer 122 at the first opening OP1.

Referring to FIG. 7D, a bank 116 can be deposited to define the emitting area EA. Specifically, the photoresist layer PR can be removed after the first convex and concave pattern PT1 is formed, and the bank can be deposited to cover the edges of the first transparent conductive layer 121 and the reflective layer 122.

Referring to FIG. 7E, depositing the second transparent conductive layer 123 can be performed. Further, since the second transparent conductive layer 123 is deposited on the reflective layer 122, a part of the second transparent conductive layer 123, disposed at the first opening OP1, can be deposited in a curved shape because of the shape of the first convex and concave pattern PT1.

Referring to FIG. 7F, to embody a micro cavity structure, the third transparent conductive layer 124 is deposited to complete manufacturing of the first electrode 120G. Further, this process can be omitted in the third sub pixel SP3 to embody the micro cavity structure, and depositing the fourth transparent conductive layer 125 as well as the third transparent conductive layer 124 can be further performed in the first sub pixel SP1.

Finally, referring to FIG. 7G, the light emitting part 130 and the second electrode 140 are consecutively deposited on the first electrode 120G and the bank 116, to complete the manufacturing process.

Examples of the embodiments of the present disclosure can also be described as follows:

According to an aspect of the present disclosure, there is provided a display device. The display device includes a substrate on which a plurality of sub pixels each comprising an emitting area and a non-emitting area are defined; a thin film transistor disposed in each of the plurality of sub pixels; a planarization layer disposed on the thin film transistor, and comprising a first opening disposed in at least one of the emitting area; a first electrode disposed on an upper surface of the planarization layer and the first opening in at least one of the plurality of sub pixels, and connected to the thin film transistor; and a bank exposing a part of the first electrode on the planarization layer, and defining the emitting area. The first electrode comprises a first convex and concave pattern formed in an area at the first opening.

The first electrode can comprise a reflective layer, and at least one transparent conductive layer disposed on at least one surface of the reflective layer, and the reflective layer can be disposed on the upper surface of the planarization layer and at the first opening.

The reflective layer can comprise silver (Ag).

The plurality of sub pixels can comprise a first sub pixel, a second sub pixel and a third sub pixel emitting light of different colors respectively, a first electrode of the first sub pixel can have a greater thickness than a first electrode of the second sub pixel, and the first electrode of the second sub pixel can have a greater thickness than a first electrode of the third sub pixel.

At least one transparent conductive layer can comprise a first transparent conductive layer under the reflective layer; and a second transparent conductive layer on the reflective layer. In the second sub pixel, at least one transparent conductive layer can further comprise a third transparent conductive layer disposed on the second transparent conductive layer on the planarization layer not having the first opening. And, in the first sub pixel, at least one transparent conductive layer can further comprise a third transparent conductive layer and a fourth transparent conductive layer disposed on the second transparent conductive layer on the planarization layer not having the first opening.

The first sub pixel can be a red sub pixel, the second sub pixel can be a green sub pixel, and the third sub pixel can be a blue sub pixel.

The first convex and concave pattern can have a coagulated particle shape formed from the reflective layer.

The first convex and concave pattern can be formed in such a way that silver (Ag) comprised by the reflective layer is exposed to ultraviolet rays and is thermally treated.

The first convex and concave pattern can be disposed on a lateral surface of the planarization layer at the first opening.

The display device can further comprise a passivation layer disposed between the thin film transistor and the planarization layer, and the first opening can expose the passivation layer.

The first electrode can contact the passivation layer.

The passivation layer can comprise a second opening overlapping the first opening, and the first electrode can be extended to the second opening.

The thin film transistor can be disposed in the emitting area, and the first electrode can connect to the thin film transistor through the second opening.

The planarization layer can have a height of 1.0 μm-1.2 μm.

A ratio of a width of the first opening and a gap between the first openings can be at 1:1-1:1.5.

The first opening can be shaped into a planar rectangle or a planar hexagon.

The first opening can be shaped into a slit.

The planarization layer can further comprise a third opening disposed in the non-emitting area. Further, the first electrode can be extended to the third opening, and can further comprise a second convex and concave pattern formed in an area at the third opening.

The second convex and concave pattern can be disposed on a lateral surface of the planarization layer at the third opening.

The planarization layer disposed in the non-emitting aera can have a greater height than the planarization layer disposed in the emitting area, and at least a part of the second convex and concave pattern can be disposed at a higher position than the planarization layer disposed in the emitting area.

The display device can further comprise a plurality of color filters disposed on the planarization layer in the emitting area; and a black matrix disposed among the plurality of color filters in the non-emitting area. The third opening can overlap the black matrix.

The first electrode disposed in the emitting area and the first electrode disposed in the non-emitting area can be spaced from each other due to the third opening.

The first electrode disposed in the emitting area can comprise a reflective layer, a first transparent conductive layer under the reflective layer, and a second transparent conductive layer on the reflective layer. And, the first electrode disposed in the non-emitting area can comprise the reflective layer and the first transparent conductive layer under the reflective layer only.

According to another aspect of the present disclosure, there provided a manufacturing method of the display device as described above.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate on which a plurality of sub pixels are defined, each of the plurality of sub pixels comprising an emitting area and a non-emitting area;
a thin film transistor disposed in each of the plurality of sub pixels;
a planarization layer disposed on the thin film transistor, and comprising a first opening disposed in at least one of the emitting areas;
a first electrode disposed on an upper surface of the planarization layer and the first opening in at least one of the plurality of sub pixels, the first electrode being connected to the thin film transistor; and
a bank exposing a part of the first electrode on the planarization layer, and defining the emitting area,
wherein the first electrode comprises a first convex and concave pattern formed in an area at the first opening.

2. The display device of claim 1, wherein the first electrode comprises a reflective layer, and at least one transparent conductive layer disposed on at least one surface of the reflective layer, and
the reflective layer is disposed on the upper surface of the planarization layer and at the first opening.

3. The display device of claim 2, wherein the reflective layer comprises silver (Ag).

4. The display device of claim 2, wherein the plurality of sub pixels comprise a first sub pixel, a second sub pixel and a third sub pixel configured to emit light of different colors respectively,
a first electrode of the first sub pixel has a greater thickness than a first electrode of the second sub pixel, and
the first electrode of the second sub pixel has a greater thickness than a first electrode of the third sub pixel.

5. The display device of claim 4, wherein the at least one transparent conductive layer comprises:
a first transparent conductive layer disposed under the reflective layer; and
a second transparent conductive layer disposed on the reflective layer,
wherein in the second sub pixel, the at least one transparent conductive layer further comprises a third transparent conductive layer disposed on the second transparent conductive layer on the planarization layer not having the first opening, and
in the first sub pixel, the at least one transparent conductive layer further comprises a third transparent conductive layer and a fourth transparent conductive layer disposed on the second transparent conductive layer on the planarization layer not having the first opening.

6. The display device of claim 4, wherein the first sub pixel is a red sub pixel, the second sub pixel is a green sub pixel, and the third sub pixel is a blue sub pixel.

7. The display device of claim 2, wherein the first convex and concave pattern has a coagulated particle shape formed from the reflective layer.

8. The display device of claim 7, wherein the first convex and concave pattern is formed so that silver (Ag) comprised by the reflective layer is exposed to ultraviolet rays and is thermally treated.

9. The display device of claim 2, wherein the first convex and concave pattern is disposed on a lateral surface of the planarization layer at the first opening.

10. The display device of claim 1, further comprising a passivation layer disposed between the thin film transistor and the planarization layer,
wherein the first opening exposes the passivation layer.

11. The display device of claim 10, wherein the first electrode contacts the passivation layer.

12. The display device of claim 10, wherein the passivation layer comprises a second opening overlapping the first opening, and
the first electrode is extended to the second opening.

13. The display device of claim 12, wherein the thin film transistor is disposed in the emitting area, and
the first electrode connects to the thin film transistor through the second opening.

14. The display device of claim 1, wherein the planarization layer has a height of 1.0 μm-1.2 μm.

15. The display device of claim 14, wherein a ratio of a width of the first opening and a gap between the first openings is at 1:1-1:1.5.

16. The display device of claim 1, wherein the first opening is shaped into a planar rectangle or a planar hexagon.

17. The display device of claim 1 wherein the first opening is shaped into a slit.

18. The display device of claim 1, wherein the planarization layer further comprises a third opening disposed in the non-emitting area, and
the first electrode is extended to the third opening, and further comprises a second convex and concave pattern formed in an area at the third opening.

19. The display device of claim 18, wherein the second convex and concave pattern is disposed on a lateral surface of the planarization layer at the third opening.

20. The display device of claim 18, wherein the planarization layer disposed in the non-emitting area has a greater height than the planarization layer disposed in the emitting area, and
at least a part of the second convex and concave pattern is disposed at a higher position than the planarization layer disposed in the emitting area.

21. The display device of claim 20, further comprising:
a plurality of color filters disposed on the planarization layer in the emitting area; and
a black matrix disposed among the plurality of color filters in the non-emitting area,
wherein the third opening overlaps the black matrix.

22. The display device of claim 18, wherein the first electrode disposed in the emitting area and the first electrode disposed in the non-emitting area are spaced from each other due to the third opening.

23. The display device of claim 18, wherein the first electrode disposed in the emitting area comprises a reflective layer, a first transparent conductive layer disposed under the reflective layer, and a second transparent conductive layer disposed on the reflective layer, and
the first electrode disposed in the non-emitting area comprises the reflective layer and the first transparent conductive layer disposed under the reflective layer only.
